(19) United States
(12) Patent Application Publication
(10) Pub. No.: US 2026/0131364 A1
(43) Pub. Date: May 14, 2026

(54) SUBSTRATE PROCESSING APPARATUS AND SUBSTRATE PROCESSING METHOD

(71) Applicant: SEMES CO., LTD., Cheonan-si (KR)

(72) Inventors: Jeong Bo SHIM, Suwon-si (KR); In Ki JUNG, Seongnam-si (KR); Ho Jong HWANG, Hwaseong-si (KR); Jun Ho SONG, Hwaseong-si (KR); Se Hoon OH, Cheonan-si (KR)

(73) Assignee: SEMES CO., LTD., Cheonan-si (KR)

(21) Appl. No.: 19/385,697

(22) Filed: Nov. 11, 2025

(30) Foreign Application Priority Data
Nov. 12, 2024 (KR) 10-2024-0159816

(51) Int. Cl. B08B 13/00; H01L 21/67

(52) U.S. Cl. CPC B08B 13/00; H10P 72/0414

(57) ABSTRACT

Provided is an apparatus for processing a substrate. The apparatus includes standby port which is located on one side of a cup unit and in which a nozzle is located after supplying a treatment liquid. The standby port includes: an outer wall with an inner space; a first gas discharge port provided to supply gas toward one side of the nozzle accommodated in the standby port; and a second gas discharge port provided to supply gas independently of the first gas discharge port toward the other side of the nozzle accommodated in the standby port. The first gas discharge port and the second gas discharge port are provided at mutually opposite positions.

### CROSS-REFERENCE TO RELATED APPLICATION

This application claims priority to and the benefit of Korean Patent Application No. 10-2024-0159816 filed in the Korean Intellectual Property Office on Nov. 12, 2024, the entire contents of which are incorporated herein by reference.

### TECHNICAL FIELD

The present invention relates to an apparatus for processing a substrate and a method of processing a substrate, and more specifically, to a substrate processing apparatus having a standby port in which a nozzle discharging a treatment liquid to a substrate waits, and a substrate processing method using the same.

### BACKGROUND ART

To manufacture a semiconductor device or liquid crystal display, various processes, such as photolithography, etching, ashing, ion implantation, thin film deposition, and cleaning, are performed on a substrate. Among them, the cleaning process is a process of removing particles on the substrate by supplying a treatment liquid, such as chemical, organic solvent, or water, onto the substrate. A typical device for performing a cleaning process has a spin chuck supporting a substrate in a treatment space provided in a cup and a nozzle for supplying a treatment liquid onto the substrate. When the cleaning of the substrate is not performed, the nozzle waits in a standby unit located on one side of the cup after cleaning.

When the treatment liquid is supplied onto the substrate, the treatment liquid is bounced back to the nozzle and contaminates the nozzle. The treatment liquid solidified at the end of the nozzle acts as particles when processing the subsequent substrate, contaminating the subsequent substrate.

FIG. 1 is a cross-sectional view schematically illustrating a structure of a general standby port, and FIG. 2 is a plan view schematically illustrating the standby port of FIG. 1.

Referring to FIGS. 1 and 2, a cleaning nozzle 650 for supplying a cleaning liquid is installed on a side surface of the standby port 900. When the nozzle 490 is inserted into the standby port 900, the cleaning liquid is supplied from the cleaning nozzle 650 toward an end 494 or the outer surface of the nozzle 490. However, in the structure as illustrated in FIGS. 1 and 2, the entire circumferential surface of the nozzle 490 is not uniformly cleaned. Furthermore, when a plurality of nozzles 490 is simultaneously cleaned at the standby port 900, the cleaning efficiency of some nozzles 490 is greatly reduced depending on the arrangement position of the nozzles 490.

In addition, as a number of cleaning nozzles 650 is installed, the structure in the standby port 900 becomes more complex, and the number of components provided to the standby port 900 increases.

Additionally, when the cleaning nozzles 650 are installed on opposite sides of the nozzle 490, respectively, the cleaning liquid discharged from the opposite cleaning nozzle 650 collides with each other and a large amount of cleaning liquid is scattered.

### SUMMARY OF THE INVENTION

The present invention has been made in an effort to provide a substrate processing apparatus having a standby port capable of improving cleaning efficiency of a nozzle used in substrate processing, and a substrate processing method using the same.

The present invention has also been made in an effort to provide a substrate processing apparatus having a standby port that may reduce the amount of cleaning liquid scattered when a nozzle is cleaned in a standby port, and a substrate processing method using the same.

The present invention has also been made in an effort to provide a substrate processing apparatus having a standby port that may prevent significant degradation in cleaning efficiency of some nozzles when a plurality of nozzles is inserted into the standby port at the same time, and a substrate processing method using the same.

The objectives of the present disclosure are not limited thereto and other objectives not stated herein may be clearly understood by those skilled in the art from the following description.

An exemplary embodiment of the present disclosure, an apparatus for processing a substrate, the apparatus comprising: a cup unit having a treatment space for liquid-treating a substrate with a treatment liquid; a support unit for supporting the substrate within the treatment space; a nozzle unit including a nozzle that supplies a treatment liquid to the substrate supported by the support unit; and a standby port which is positioned on one side of the cup unit and in which the nozzle is located after supplying the treatment liquid, wherein the standby port includes: an outer wall with an inner space; a first gas discharge port provided to supply gas toward one side of the nozzle accommodated in the standby port; and a second gas discharge port provided to supply gas independently of the first gas discharge port toward the other side of the nozzle accommodated in the standby port, and the first gas discharge port and the second gas discharge port may be provided at mutually opposite positions.

According to the exemplary embodiment of the present invention, wherein the standby port may includes, a first exhaust port that is arranged opposite a region where the second gas discharge port is provided to exhaust an atmosphere from the inner space to the outside; and a second exhaust port that is arranged opposite a region where the first gas discharge port is provided to exhaust an atmosphere from the inner space to the outside.

According to the exemplary embodiment of the present invention, wherein the first exhaust pipe connected to the first exhaust port is connected to the first gas supply pipe, which is connected to the first gas discharge port to supply gas, the second exhaust pipe connected to the second exhaust port is connected to the second gas supply pipe, which is connected to the second gas discharge port to supply gas, the first gas discharge port also may functions as the first exhaust port, and the second gas discharge port is configured to function as the second exhaust port.

According to the exemplary embodiment of the present invention, wherein a part of the first gas discharge ports is provided to be inclined downward toward the inner space, and a part of the second gas discharge ports may be provided to be inclined downward toward the inner space.

According to the exemplary embodiment of the present invention, wherein another part of the first gas discharge ports is provided to discharge gas in a horizontal direction toward the inner space, among the first gas discharge ports, a first gas discharge port for discharging gas in a downwardly inclined direction is disposed above the first gas discharge ports that discharge gas in a horizontal direction, and another part of the second gas discharge ports is provided to discharge gas in a horizontal direction toward the inner space, and among the second gas discharge ports, a second gas discharge port for discharging gas in a downwardly inclined direction may be disposed above the second gas discharge ports that discharge gas in a horizontal direction.

According to the exemplary embodiment of the present invention, wherein the standby port includes: a first liquid discharge port that supplies a cleaning liquid toward one side of the nozzle accommodated in the standby port; and a second liquid discharge port that supplies a cleaning liquid toward the other side of the nozzle accommodated in the standby port, and the first liquid discharge port and the second liquid discharge port may be provided at opposite positions.

According to the exemplary embodiment of the present invention, wherein the first liquid discharge port and the second liquid discharge port may be provided at lower positions than the first gas discharge port and the second gas discharge port.

According to the exemplary embodiment of the present invention, wherein a part of the first liquid discharge ports is provided to be inclined downward toward the inner space, a part of the second liquid discharge ports is provided to be inclined downward toward the inner space, another part of the first liquid discharge ports is provided to discharge a cleaning liquid in a horizontal direction toward the inner space, another part of the second liquid discharge ports is provided to discharge a cleaning liquid in a horizontal direction toward the inner space, among the first liquid discharge ports, a first liquid discharge port for discharging a cleaning liquid in a downwardly inclined direction is disposed above the first liquid discharge ports that discharge a cleaning liquid in a horizontal direction, and among the second liquid discharge ports, a second liquid discharge port for discharging a cleaning liquid in a downwardly inclined direction may be disposed above the second liquid discharge ports that discharge a cleaning liquid in a horizontal direction.

According to the exemplary embodiment of the present invention, wherein the standby port includes: a second inner wall, which is provided in the inner space, and divides the inner space into a drying space where the nozzle is positioned and dried, and a gas buffer space formed outside the drying space and provided in a ring shape surrounding the drying space; and a second partition wall provided in the gas buffer space and separating the gas buffer space into a first gas space and a second gas space, and the first gas discharge port and the second gas discharge port may be formed in the second inner wall.

According to the exemplary embodiment of the present invention, wherein the first gas discharge port and the second gas discharge port are formed to form rows in a direction along a circumference of the second inner wall, a plurality of rows is provided in a vertical direction, and the first gas discharge port and the second gas discharge port constituting the row disposed at the top of the rows may be formed to be inclined downward toward the drying space.

According to the exemplary embodiment of the present invention, wherein the standby port includes: a first inner wall that is provided in the inner space and divides the inner space into a cleaning space where the nozzle is positioned and cleaned, and a liquid buffer space formed outside the cleaning space and provided in a ring shape surrounding the cleaning space; a first partition wall provided in the liquid buffer space and separating the liquid buffer space into a first liquid space and a second liquid space; a first liquid discharge port that supplies a cleaning liquid toward one side of the nozzle accommodated in the standby port; and a second liquid discharge port that supplies a cleaning liquid toward the other side of the nozzle accommodated in the standby port, and the first liquid discharge port and the second liquid discharge port are formed in the first inner wall to allow the cleaning liquid to may flow between the liquid buffer space and the cleaning space.

An exemplary embodiment of the present disclosure, a method of processing a substrate, the method may comprising, a substrate processing operation of processing a substrate by supplying a treatment liquid from a nozzle to the substrate supported by a support unit provided in a liquid treating chamber; an operation of moving the nozzle from the liquid treating chamber to a standby port; and a nozzle treating operation of removing foreign substances attached to the nozzle in the standby port, the nozzle treating operation may includes: a drying space movement operation in which the nozzle moves to a drying space within the standby port; and a nozzle drying operation of discharging gas toward the nozzle to dry the nozzle, and the nozzle drying operation includes: a first drying operation of injecting gas to one side of the nozzle only from a first gas discharge port among first gas discharge ports and second gas discharge ports arranged opposite to each other; and a second drying operation of injecting gas to the other side of the nozzle only from the second gas discharge port among the first gas discharge ports and the second gas discharge ports.

According to the exemplary embodiment of the present invention, wherein the first drying operation and the second drying operation may be alternately and repeatedly performed.

According to the exemplary embodiment of the present invention, wherein the gas is exhausted from a second exhaust port disposed at a position opposite to the first gas discharge port while the gas is discharged from the first gas discharge port, and the gas is exhausted from a first exhaust port disposed at a position opposite to the second gas discharge port while the gas may be discharged from the second gas discharge port.

According to the exemplary embodiment of the present invention, wherein the first gas discharge port is configured to function as the first exhaust port, and the second gas discharge port also may functions as the second exhaust port.

According to the exemplary embodiment of the present invention, wherein the nozzle treating operation may includes: a secondary drying space movement operation in which the nozzle moves to a secondary drying space arranged above a drying space from the drying space in the standby port after the nozzle drying operation is performed; and a second drying operation of drying the nozzle by discharging gas at a pressure lower than a pressure of the gas discharged in the nozzle drying operation toward the nozzle after the secondary drying space movement operation is performed.

According to the exemplary embodiment of the present invention, wherein the secondary drying operation may includes: a third drying operation of injecting gas to one side of the nozzle only from a third gas discharge port among third gas discharge ports and fourth gas discharge ports arranged opposite to each other; and a fourth drying operation of injecting gas to the other side of the nozzle only from the fourth gas discharge port among the third gas discharge ports and the fourth gas discharge ports.

According to the exemplary embodiment of the present invention, wherein the nozzle treating operation includes: a cleaning space movement operation of placing the nozzle in a cleaning space before the nozzle drying operation is performed; and a nozzle cleaning operation of cleaning the nozzle by discharging a cleaning liquid toward the nozzle after the cleaning space movement operation is performed, and the nozzle cleaning operation further may includes, a first cleaning operation of injecting a cleaning liquid to one side of the nozzle only from a first liquid discharge port among first liquid discharge ports and second liquid discharge ports arranged opposite to each other; and a second cleaning operation of injecting a cleaning liquid to the other side of the nozzle only from a second liquid discharge port among the first liquid discharge ports and the second liquid discharge ports arranged opposite to each other.

According to the exemplary embodiment of the present invention, wherein the first cleaning operation and the second cleaning operation may be alternately and repeatedly performed.

An exemplary embodiment of the present disclosure, an apparatus for processing a substrate, the apparatus comprising: a cup unit having a treatment space for liquid-treating a substrate with a treatment liquid; a support unit for supporting the substrate within the treatment space; a nozzle unit including a nozzle that supplies a treatment liquid to the substrate supported by the support unit; and a standby port which is located on one side of the cup unit and in which the nozzle is located after supplying the treatment liquid, the standby port includes: an outer wall with an inner space; a first inner wall that is provided in the inner space and divides the inner space into a cleaning space where the nozzle is positioned and cleaned, and a liquid buffer space formed outside the cleaning space and provided in a ring shape surrounding the cleaning space; a second inner wall that is provided in the inner space, and divides the inner space into a drying space where the nozzle is positioned and is dried at a position higher than the cleaning space, and a gas buffer space formed outside the drying space and provided in a ring shape surrounding the drying space; a first partition wall provided in the liquid buffer space and separating the liquid buffer space into a first liquid space and a second liquid space; a second partition wall provided in the gas buffer space and separating the gas buffer space into a first gas space and a second gas space; a first liquid discharge port that supplies a cleaning liquid toward one side of the nozzle accommodated in the standby port; a second liquid discharge port that supplies a cleaning liquid toward the other side of the nozzle accommodated in the standby port; a first gas discharge port that supplies gas toward one side of the nozzle accommodated in the standby port; a second gas discharge port that supplies gas toward the other side of the nozzle accommodated in the standby port; a first exhaust port that exhausts an atmosphere from one side of the nozzle accommodated in the standby port to the outside; and a second exhaust port that exhausts an atmosphere from the other side of the nozzle accommodated in the standby port to the outside, the first gas discharge port and the second gas discharge port are provided at mutually opposite positions, the first liquid discharge port and the second liquid discharge port may be provided at mutually opposite positions, the first gas discharge port is configured to function as the first exhaust port, and the second gas discharge port is configured to function as the second exhaust port.

According to the exemplary embodiment of the present invention, it is possible to improve the cleaning efficiency of a nozzle used for substrate processing.

Further, according to the exemplary embodiment of the present invention, it is possible to reduce the amount of cleaning liquid scattered when a nozzle is cleaned in a standby port.

Further, according to the exemplary embodiment of the present invention, it is possible to prevent significant degradation in cleaning efficiency of some nozzles when a plurality of nozzles is inserted into the standby port at the same time.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a cross-sectional view schematically illustrating a structure of a general standby port.

FIG. 2 is a plan view of the general standby port of FIG. 1.

FIG. 3 is a top plan view schematically illustrating a substrate processing apparatus according to an exemplary embodiment of the present invention.

FIG. 4 is a diagram schematically illustrating an exemplary embodiment of a liquid treating chamber of FIG. 3.

FIG. 5 is a diagram schematically illustrating an exemplary embodiment of a nozzle unit of FIG. 4.

FIG. 6 is a perspective view schematically illustrating an exemplary embodiment of a standby port of FIG. 4.

FIG. 7 is a longitudinal sectional view taken along line A-A′ at the standby port of FIG. 6.

FIG. 8 is a flowchart schematically illustrating a nozzle cleaning method according to an exemplary embodiment of the present invention.

FIG. 9 is a cross-sectional view schematically illustrating a position of a nozzle in a cleaning space movement operation of FIG. 8.

FIGS. 10 and 11 are a cross-sectional view and a plan view schematically illustrating a flow of a cleaning liquid in a first cleaning operation of FIG. 8, respectively.

FIGS. 12 and 13 are a cross-sectional view and a plan view schematically illustrating a flow of a cleaning liquid in a second cleaning operation of FIG. 8, respectively.

FIG. 14 is a cross-sectional view schematically illustrating a position of a nozzle in a drying space movement operation of FIG. 8.

FIGS. 15 and 16 are a cross-sectional view and a plan view schematically illustrating the flow of gas in a first drying operation of FIG. 8.

FIGS. 17 and 18 are a cross-sectional view and a plan view schematically illustrating the flow of gas in a second drying operation of FIG. 8.

FIGS. 19 to 24 are respectively diagrams schematically illustrating a modified example of the standby port of FIG. 6.

FIG. 25 is a cross-sectional view schematically illustrating another exemplary embodiment of the standby port according to the exemplary embodiment of the present invention, and FIG. 26 is a flowchart schematically illustrating an exemplary embodiment of a substrate processing method according to the standby port of FIG. 25.

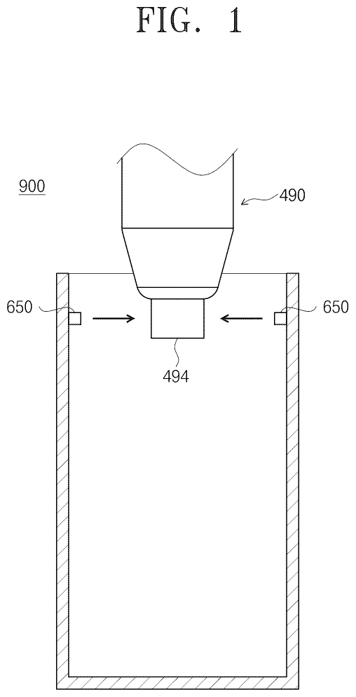

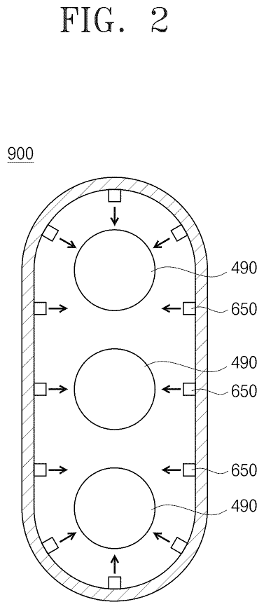

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

In the present invention, a wafer used for manufacturing a semiconductor is described as an example of a substrate. However, unlike this, the substrate may be a mask or a flat panel display panel.

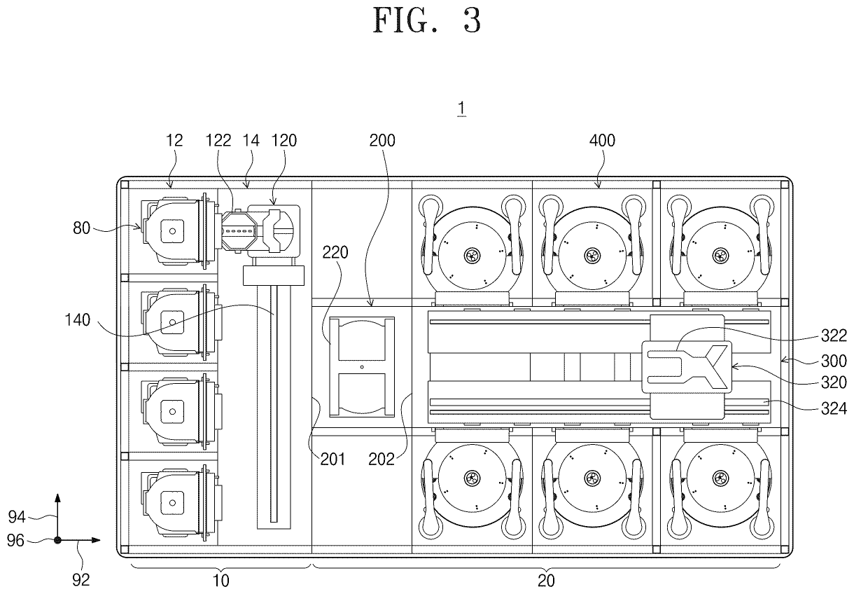

FIG. 3 is a top plan view schematically illustrating a substrate processing apparatus according to an exemplary embodiment of the present invention.

Referring to FIG. 3, a substrate processing apparatus 1 includes an index module 10, a treating module 20, and a controller 2. The index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely processed in the treating module 20, be accommodated in the container 80. A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plural, and the plurality of load ports 12 may be disposed in the second direction 94.

An index robot 120 is provided to the index frame 14. A guide rail 140 of which a longitudinal direction is the second direction 94 is provided within the index frame 14, and the index robot 120 may be provided to be movable along the guide rail 140. The index robot 120 includes a hand 122 on which the substrate W is placed. The hand 122 may be provided to move forward and backward, rotate around the third direction 96, and be movable along the third direction 96. The plurality of hands 122 is provided while being spaced apart from each other in the up and down direction, and is capable of independently moving forward and backward.

The treating module 20 includes a buffer unit 200, a transfer chamber 300, and a liquid treating chamber 400.

The buffer unit 200 provides a space in which the substrate W moved between the index module 10 and the transfer chamber 300 temporarily stays. The liquid treating chamber 400 performs a liquid treatment process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction thereof is the first direction 92. The buffer unit 200 may be disposed between the index module 10 and the transfer chamber 300. A plurality of liquid treating chambers 400 is provided. The liquid treating chamber 400 may be disposed on a side portion of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 whose longitudinal direction is provided in the first direction 92 is provided within the transfer chamber 300, and the transfer robot 320 may be provided to be movable on the guide rail 340. The transfer robot 320 includes a hand 322 on which the substrate W is placed. The hand 322 may be provided to move forward and backward, rotate around the third direction 96, and be movable along the third direction 96. The plurality of hands 322 is provided while being spaced apart from each other in the vertical direction, and is capable of independently moving forward and backward.

The buffer unit 200 includes a plurality of buffers 220 on which the substrate W is placed. The buffers 220 may be disposed while being spaced apart from each other in the third direction 96. A front face 201 and a rear face 202 of the buffer unit 200 are opened. The front face 201 of the buffer unit 200 is a face facing the index module 10, and the rear face 202 of the buffer unit 200 is a face facing the transfer chamber 300. The index robot 120 may approach the inside of the buffer unit 200 through the front face 201 of the buffer unit 200, and the transfer robot 320 may approach the buffer unit 200 through the rear face 202 of the buffer unit 200.

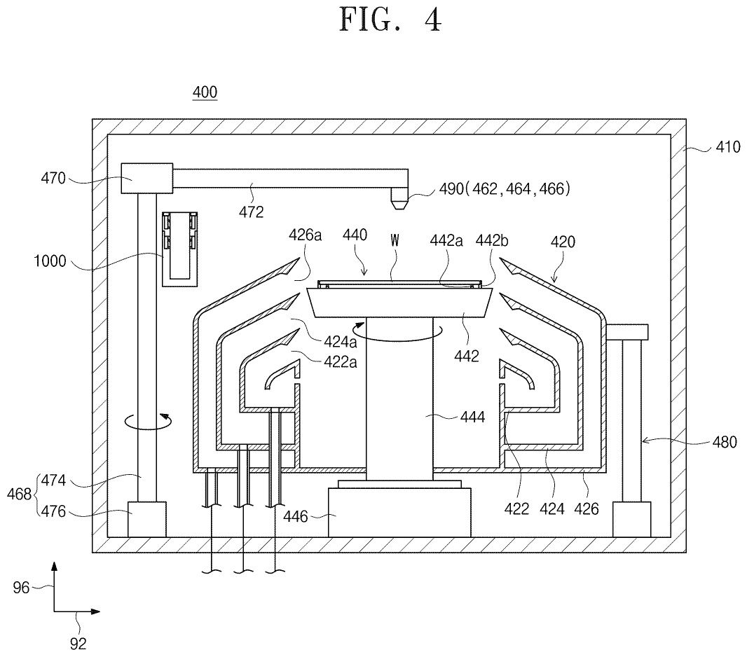

FIG. 4 is a diagram schematically illustrating an exemplary embodiment of a liquid treating chamber of FIG. 3.

Referring to FIG. 4, the liquid treating chamber 400 includes a housing 410, a cup 420, a support unit 440, a lifting unit 480, a nozzle unit 460, and a standby port 1000.

The housing 410 is provided in a generally rectangular parallelepiped shape. The cup 420, the support unit 440, the nozzle unit 460, the lifting unit 480, and the standby port 1000 are disposed within the housing 410.

The cup 420 has a treatment space 402 in which an upper portion is opened. The cup 420 includes a plurality of recovery containers 422, 424, and 426. Each of the recovery containers 422, 424, and 426 has a recovery space for recovering the liquid used for the treatment of the substrate. Each of the recovery containers 422, 424, and 426 is provided in a ring shape surrounding the support unit 440. As the liquid treatment process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 supports the substrate W in the treatment space 402. The support unit 440 includes a spin chuck 442 and a drive shaft 444. An upper surface of the spin chuck 442 may be provided in a generally circular shape, and may have a diameter larger than a diameter of the substrate W. A chuck pin 442b is provided at an edge of the spin chuck 442. The chuck pin 442b is provided to protrude upward from the spin chuck 442. The chuck pin 442b supports a side portion of the substrate W so that the substrate W does not deviate from the support unit 440 when the substrate W is rotated. Also, a support pin 442a is provided to the spin chuck 442. The support pin 442a is provided with a top end protruding from the spin chuck 442 such that the substrate W is spaced a certain distance from the spin chuck 442. The support pin 442a is disposed closer to a center of the spin chuck 442 than the chuck pin 442b. The drive shaft 444 is driven by the driver 446, is connected to a center of a bottom surface of the substrate W, and rotates the spin chuck 442 with respect to its central axis.

The lifting unit 480 adjusts a relative height between the cup 420 and the support unit 440. According to an example, the lifting unit 480 moves the cup 420 in the vertical direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the treatment liquids may be separated and recovered. Unlike the description, the cup 420 may be fixedly installed, and the lifting unit 480 may move the support unit 440 in the vertical direction.

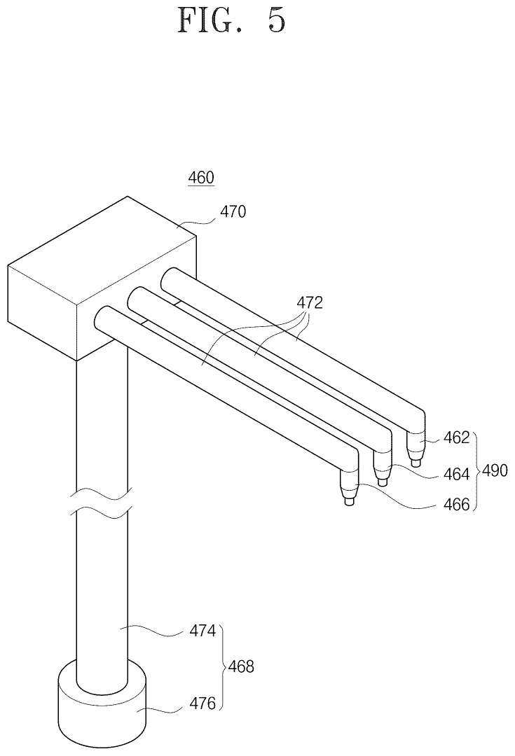

FIG. 5 is a diagram schematically illustrating an exemplary embodiment of a nozzle unit of FIG. 4.

Referring to FIG. 5, the nozzle unit 460 supplies a treatment liquid onto the substrate W supported on the support unit 440. The treatment liquid may be provided in a plurality of types, and may be sequentially supplied onto the substrate W. The nozzle unit 460 includes a support frame 470, an arm 472, a first nozzle 462, a second nozzle 464, a third nozzle 466, and a nozzle driver 468.

The first nozzle 462 supplies a first treatment liquid onto the substrate W. The second nozzle 464 supplies a second treatment liquid onto the substrate W. The third nozzle 466 supplies the third treatment liquid onto the substrate W. The first treatment liquid, the second treatment liquid, and the third treatment liquid are different types of treatment liquids. The first treatment liquid, the second treatment liquid, and the third treatment liquid may be an acidic component, an alkali component, or a neutral component. For example, the first treatment liquid, the second treatment liquid, and the third treatment liquid may be an acid component, such as sulfuric acid, hydrofluoric acid, phosphoric acid, or hydrochloric acid, or may be an alkali component, such as ammonia, or water.

Meanwhile, a nozzle unit 460 for supplying another type of treatment liquid may be further provided. For example, the nozzle unit 460 may further include a nozzle for supplying an organic solvent, such as isopropyl alcohol (IPA).

The support frame 470 supports the arm 472. A plurality of arms 472 is provided so that each nozzle 490 is installed. Each nozzle 490 is installed at an end of the arm 472. The arm 472 is provided side by side in one direction. The nozzle driver 468 has a drive shaft 474 and a driver 476. The nozzle driver 468 drives the support frame 470 such that the nozzles 490 move between a process position P and a standby position R. The process position P is a position at which the nozzle 490 supplies the treatment liquid onto the substrate W. The standby position R is a position at which the nozzle 490 which has completed supplying the treatment liquid onto the substrate W waits in the standby port 1000 until the next processing of the substrate W.

When viewed from the top, the nozzle 490 located at the standby position R overlaps the standby port 1000. The nozzle 490 is moved between the process position P and the standby position R by the nozzle driver 468. In addition, the nozzle 490 may be moved up and down in the third direction 96 by the nozzle driver 468. The standby position R is a position where a nozzle tip 494 is inserted into an inner space 1300 of the standby port 1000. The nozzle 490 located at the standby position R may discharge the treatment liquid remaining in the nozzle 490 to the standby port 1000.

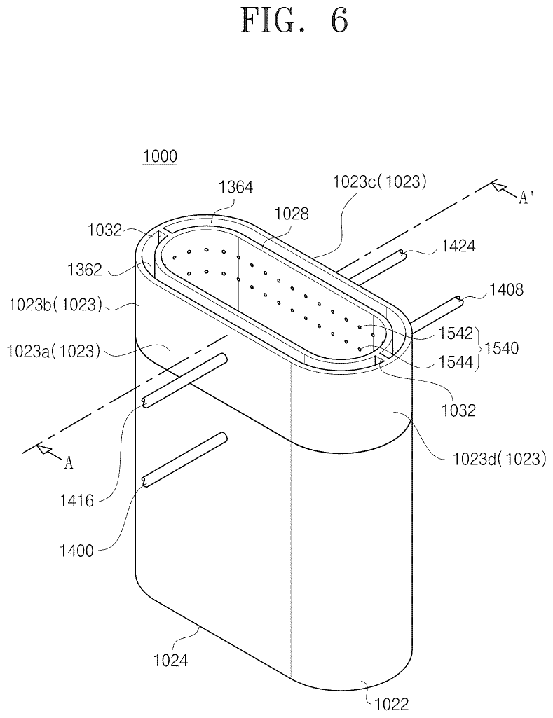

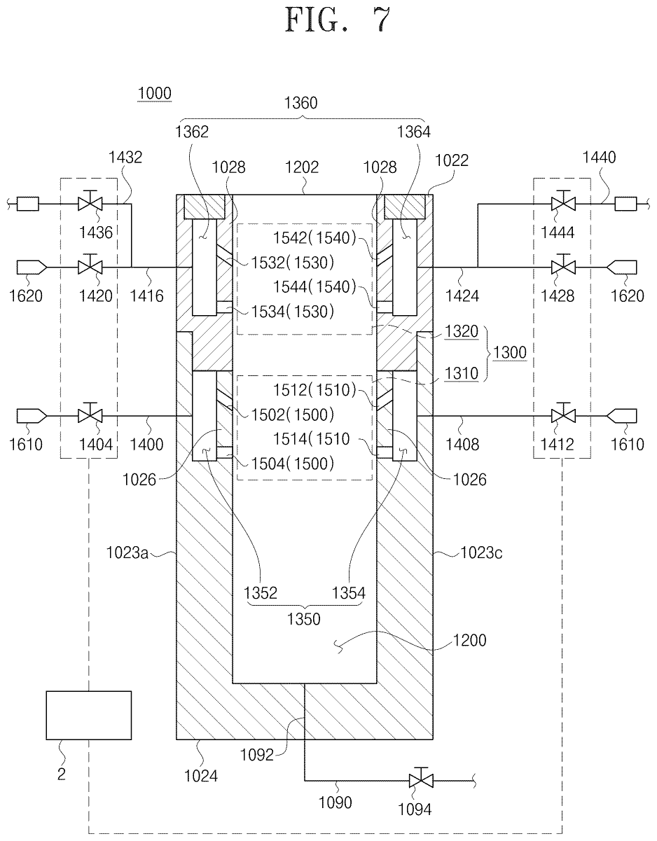

FIG. 6 is perspective view schematically illustrating an exemplary embodiment of the standby port of FIG. 4. FIG. 7 is a longitudinal sectional view taken along line A-A′ at the standby port of FIG. 6.

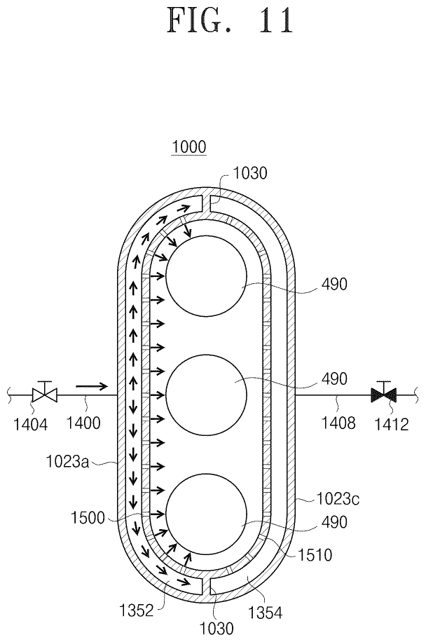

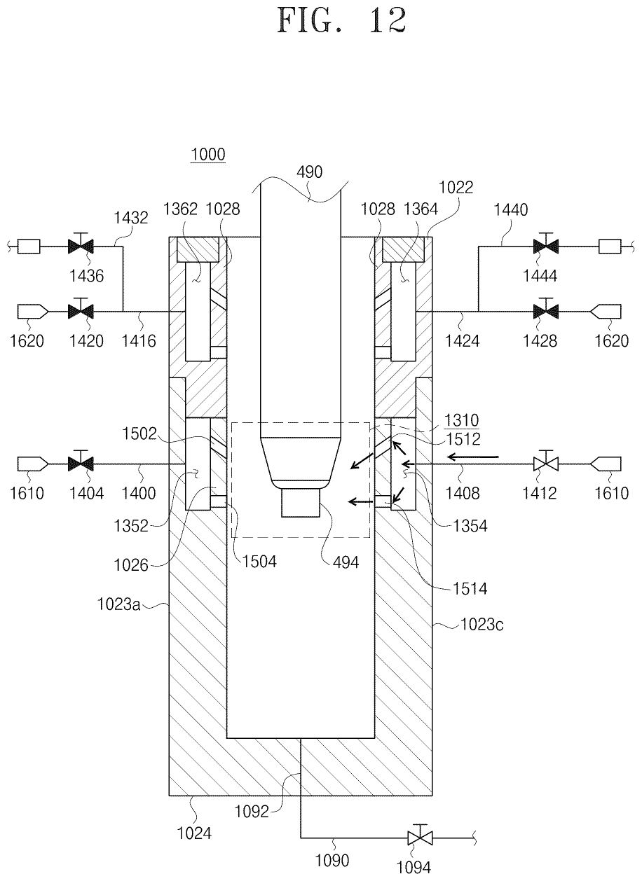

Referring to FIGS. 6 and 7, the standby port 1000 has an outer wall 1022, a first inner wall 1026, a second inner wall 1028, a first partition wall 1030 (see FIG. 11), a second partition wall 1032, a first liquid discharge port 1500, a second liquid discharge port 1510, a first gas discharge port 1530, a first gas discharge port 1540, a first exhaust port, a second exhaust port, and a discharge port 1092.

The outer wall 1022 forms the outer shape of the standby port 1000. The outer wall 1022 has a side surface 1023 and a bottom surface 1024. The side surface 1023 of the outer wall 1022 has a first surface 1023a, a second surface 1023b, a third surface 1023c, and a fourth surface 1023d. The first surface 1023a and the third surface 1023c face each other. The second surface 1023b and the fourth surface 1023d face each other. The first surface 1023a and the third surface 1023c are provided as flat surfaces. The second surface 1023b connects the first surface 1023a and the third surface 1023c. The second surface 1023b may have a convexly rounded shape in a direction toward the outside of the outer wall 1022. The fourth surface 1023d connects the first surface 1023a and the third surface 1023c. The fourth surface 1023d may have a convexly rounded shape in a direction toward an outer side of the outer wall 1022. A length between the first surface 1023a and the third surface 1023c may be provided to be shorter than a length between the second surface 1023b and the fourth surface 1023d.

A bottom surface 1022 of the outer wall 1024 is provided as a flat surface. The liquid discharge port 1092 is formed at the center of the bottom surface 1024. A liquid discharge pipe 1090 is connected to the liquid discharge port 1092. An opening/closing valve 1094 is installed in the liquid discharge pipe 1090. The treatment liquid discharged from the nozzle 490 in the standby port 1000 and a cleaning liquid for cleaning the nozzle 490 are discharged to the liquid discharge pipe 1090 through the liquid discharge port 1092.

The outer wall 1022 has an inner space 1200 surrounded by the side surface 1023 and the bottom surface 1024. An upper portion 1202 of the inner space 1200 is provided to be open.

The first inner wall 1026 is provided in the inner space 1200. The first inner wall 1026 separates a lower region of the inner space 1200 into a cleaning space 1310 and a liquid buffer space 1350. The cleaning space 1310 is a space in which the nozzle 490 is cleaned by a cleaning liquid. The liquid buffer space 1350 is located outside the cleaning space 1310. The liquid buffer space 1350 is formed in a ring shape to surround the cleaning space 1310. The first inner wall 1026 may have the same shape as the side surface 1023 of the outer wall 1022. The first inner wall 1026 may have a size smaller than that of the side surface 1023 of the outer wall 1022. A plurality of first liquid discharge ports 1500 and a plurality of second liquid discharge ports 1510 are formed in the first inner wall 1026.

The second inner wall 1028 is provided in the inner space 1200. The second inner wall 1028 separates an upper region of the inner space 1200 into a drying space 1320 and a gas buffer space 1360. The drying space 1320 is a space in which the nozzle 490 is dried by gas. The drying space 1320 is located above the cleaning space 1310. The drying space 1320 is a space that communicates with the cleaning space 1310. In this case, an upper portion of the drying space 1320 is provided in an open structure. The gas buffer space 1360 is located outside the drying space 1320. The gas buffer space 1360 is formed in a ring shape to surround the drying space 1320. The gas buffer space 1360 is provided so as not to communicate with the liquid buffer space 1350.

The gas buffer space 1360 is located above the liquid buffer space 1350.

The second inner wall 1028 may have the same shape as the side surface 1023 of the outer wall 1022. The second inner wall 1028 may have a size smaller than that of the side surface 1023 of the outer wall 1022. The second inner wall 1028 may be formed with a plurality of first gas discharge ports 1530 and a plurality of second gas discharge ports 1540.

A first partition wall 1030 is installed in the liquid buffer space 1350. The first partition wall 1030 divides the liquid buffer space 1350 into a first liquid space 1352 and a second liquid space 1354. The first partition wall 1030 may be divided so that the first liquid space 1352 and the second liquid space 1354 have the same size and shape. According to the exemplary embodiment, when viewed from above, the first partition walls 1030 may be disposed at the center of the second surface 1023b and at the center of the fourth surface 1023d of the outer wall 1022, respectively.

A first liquid supply pipe 1400 is connected to the first liquid space 1352. The first liquid supply pipe 1400 supplies the cleaning liquid from the cleaning liquid supply source 1610 to the first liquid space 1352. A second liquid supply pipe 1408 is connected to the second liquid space 1354. The second liquid supply pipe 1408 supplies the cleaning liquid from the cleaning liquid supply source 1610 to the second liquid space 1354. In one exemplary embodiment, the cleaning liquid may be pure water.

The second partition wall 1032 is installed in the gas buffer space 1360. The second partition wall 1032 divides the gas buffer space 1360 into a first gas space 1362 and a second gas space 1364. The second partition wall 1032 may divide the gas buffer space 1360 by the same volume. According to the exemplary embodiment, the second partition wall 1032 may be provided to connect the second surface 1023b and the second inner wall 1028 and to connect the fourth surface 1023d and the second inner wall 1028. According to the exemplary embodiment, the second partition wall 1032 may be provided at a middle point of the second surface 1023b and a middle point of the fourth surface 1023d. According to the exemplary embodiment, when viewed from above, the second partition wall 1032 may be provided to overlap the first partition wall 1030.

A first gas supply pipe 1416 is connected to the first gas space 1362. The first gas supply pipe 1416 supplies gas from the gas supply source 1620 to the first gas space 1362. A second gas supply pipe 1424 is connected to the second gas space 1364. The second gas supply pipe 1424 supplies gas from the gas supply source 1620 to the second gas space 1364. The gas may be air. Optionally, the gas may be inert gas such as nitrogen (N2).

The first liquid discharge port 1500 and the second liquid discharge port 1510 are formed to form a plurality of rows in a direction along the circumference of the first inner wall 1026. The first liquid discharge ports 1500 and the second liquid discharge ports 1510 may be disposed at the same interval. The first liquid discharge ports 1500 and the second liquid discharge ports 1510 are formed into a first group 1502 and 1512 and a second group 1504 and 1514. The discharge ports belonging to the same group are positioned at the same height. The discharge ports 1502 and 1512 belonging to the first group are disposed at higher positions than the discharge ports belonging to the second group 1504 and 1514. According to the exemplary embodiment, the discharge ports 1502 and 1512 belonging to the first group and the discharge ports 1504 and 1514 belonging to the second group may be formed to form one row, respectively. The discharge ports belonging to the first group 1502 and 1512 are formed to discharge a liquid in a downwardly inclined direction toward the inner space 1200. The discharge ports 1504 and 1514 belonging to the second group are formed to discharge a liquid in a horizontal direction.

The first gas discharge port 1530 and the second gas discharge port 1540 are formed to form a plurality of rows in a direction along the circumference of the second inner wall 1026. The first gas discharge ports 1530 and the second liquid discharge ports 1540 may be disposed at the same interval. The first gas discharge port 1530 and the second gas discharge port 1540 are grouped into a first group and a second group. The discharge ports belonging to the same group are positioned at the same height. The discharge ports 1532 and 1542 belonging to the first group are disposed at higher positions than the discharge ports 1534 and 1544 belonging to the second group. According to the exemplary embodiment, the discharge ports 1532 and 1542 belonging to the first group and the discharge ports 1534 and 15544 belonging to the second group may be formed to form one row, respectively. The discharge ports 1532 and 1542 belonging to the first group are formed to discharge a liquid in a downwardly inclined direction toward the inner space 1200. The discharge ports 1534 and 1544 belonging to the second group are formed to discharge a liquid in a horizontal direction.

The cleaning liquid is supplied from the first liquid supply pipe 1400 to the first liquid discharge port 1500. A first liquid valve 1404 is installed at the first liquid supply pipe 1400. The first liquid valve 1404 may be an opening/closing valve. The first liquid supply pipe 1400 supplies a cleaning liquid from the liquid supply source 1610 toward one side of the nozzle 490 located in the inner space 1200 of the standby port 1000.

A cleaning liquid is supplied from the second liquid supply pipe 1408 to the second liquid discharge port 1510. A second liquid valve 1412 is installed at the second liquid supply pipe 1408. The second liquid valve 1412 may be an opening/closing valve. The second liquid supply pipe 1408 supplies a cleaning liquid from the liquid supply source 1610 toward the other side of the nozzle 490 located in the inner space 1200 of the standby port 1000. The second liquid supply pipe 1408 is provided at positions opposite to the first liquid supply pipe 1400.

The gas is supplied from the first gas supply pipe 1416 to the first gas discharge port 1530. The first gas valve 1420 is installed at the first gas supply pipe 1416. The first gas valve 1420 may be an opening/closing valve. The first gas supply pipe 1416 supplies gas from the gas supply source 1620 toward one side of the nozzle 490 located in the inner space 1200 of the standby port 1000.

Gas is supplied from the second gas supply pipe 1424 to the second gas discharge port 1540. A second gas valve 1428 is installed at the second gas supply pipe 1424. The second gas valve 1428 may be an opening/closing valve. The second gas supply pipe 1428 supplies gas from the gas supply source 1620 toward the other side of the nozzle 490 located in the inner space 1200 of the standby port 1000.

The first exhaust port exhausts the atmosphere from one side of the nozzle 490 accommodated in the standby port 1000 to the outside. The first exhaust port exhausts the atmosphere in the inner space 1200 to the first exhaust pipe 1432. According to the exemplary embodiment, the first exhaust pipe 1432 may be connected to the first gas supply pipe 1416. In this case, the first gas discharge port 1530 may function as a first exhaust port. According to the exemplary embodiment, the first exhaust port is provided at the same height as the first gas discharge port 1530 and the second gas discharge port 1540. A first exhaust valve 1436 and a pressure reducing member are installed at the first exhaust pipe 1432. For example, the pressure reducing member may be provided with a component capable of lowering the pressure in the first exhaust pipe 1432, such as an ejector or a pump.

The second exhaust port exhausts the atmosphere from the other side of the nozzle 490 accommodated in the standby port 1000 to the outside. The second exhaust port exhausts the atmosphere in the inner space 1200 to the second exhaust pipe 1432. According to the exemplary embodiment, the second exhaust pipe 1440 may be connected to the second gas supply pipe 1424. In this case, the second gas discharge port 1540 may function as a second exhaust port. According to the exemplary embodiment, the second exhaust port is provided at the same height as the first gas discharge port 1530 and the second gas discharge port 1540. The second exhaust port is installed at a position opposite to the first exhaust port. The second exhaust valve 1444 and a pressure reducing member are installed at the second exhaust pipe 1440.

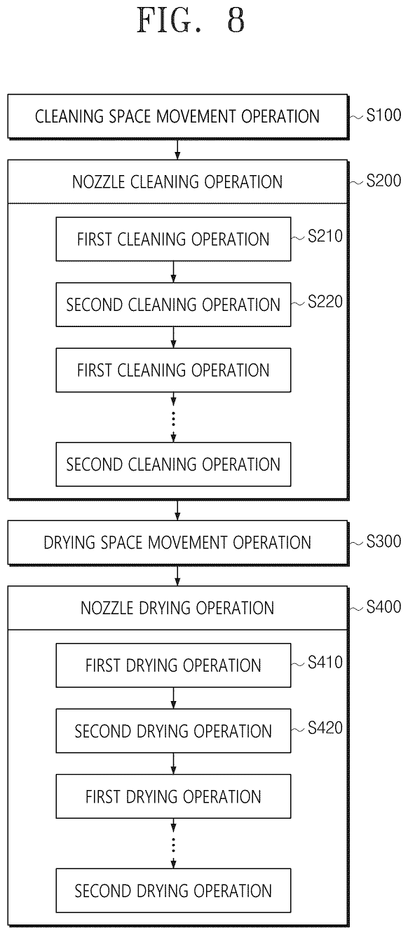

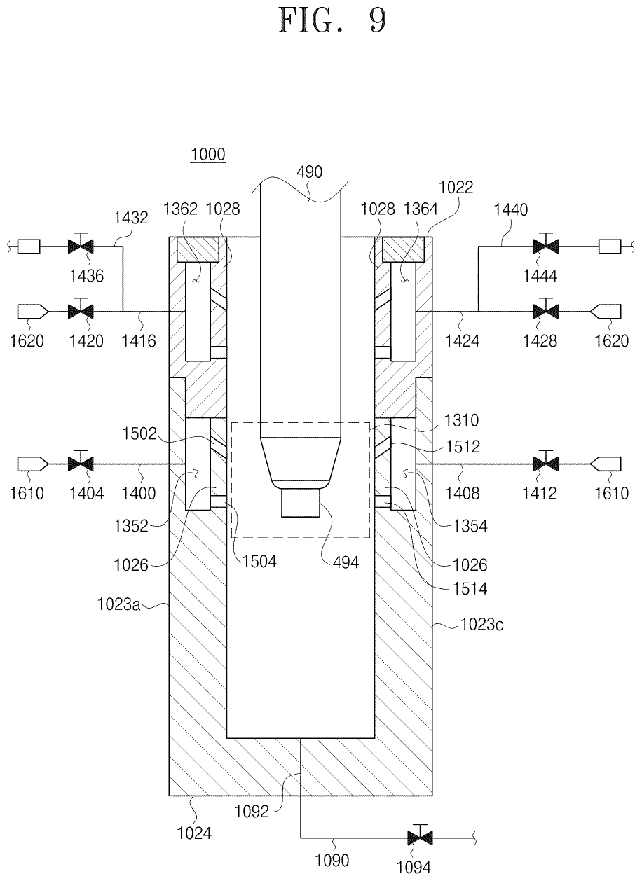

Hereinafter, a process of cleaning and drying the substrate in the standby port of FIG. 6 will be described in detail with reference to FIGS. 8 to 18.

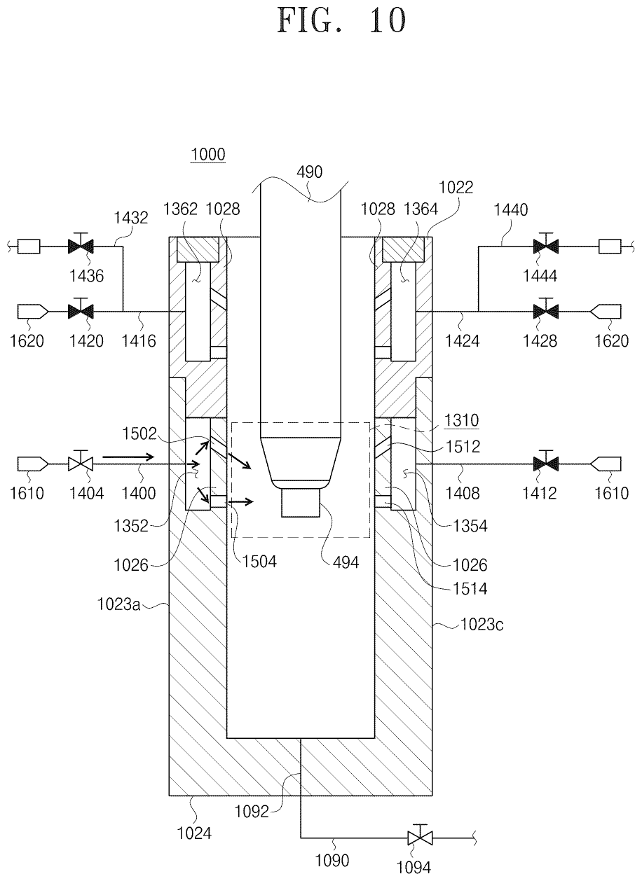

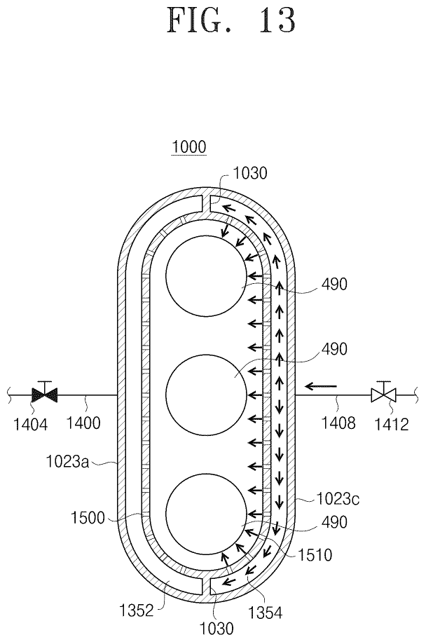

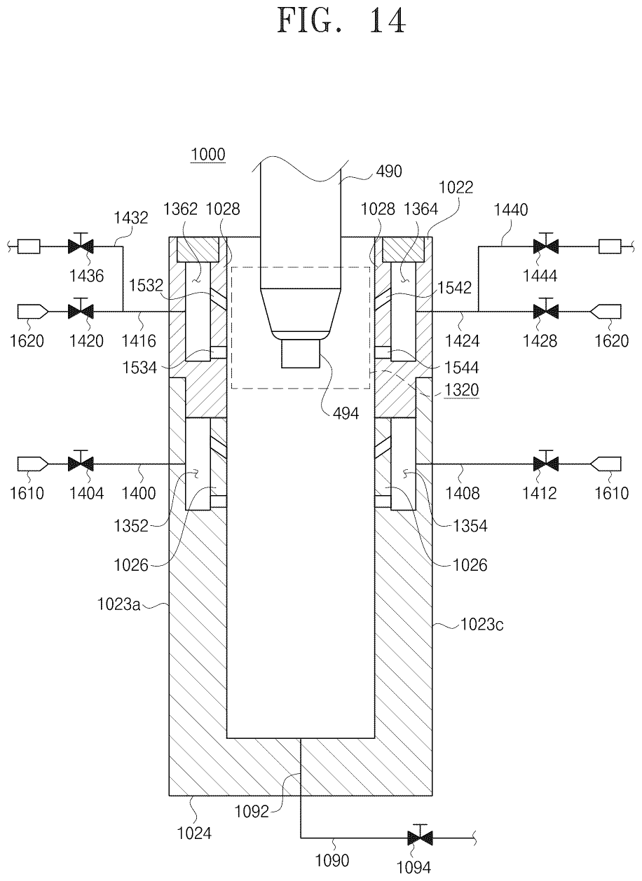

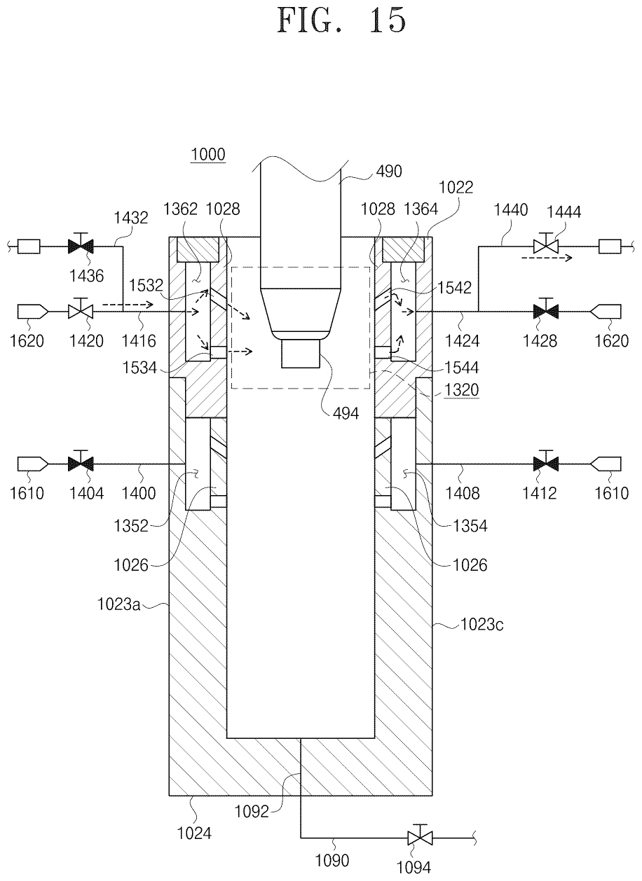

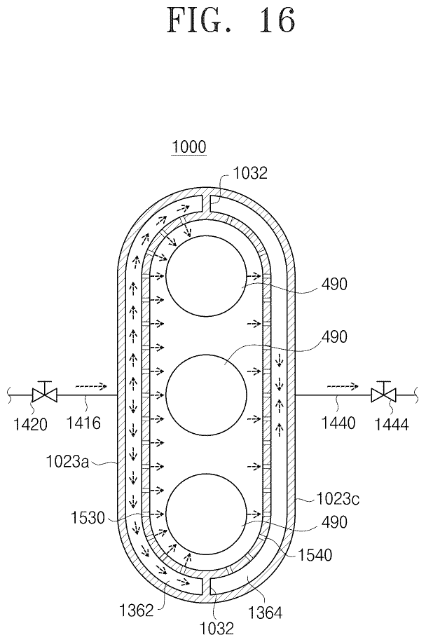

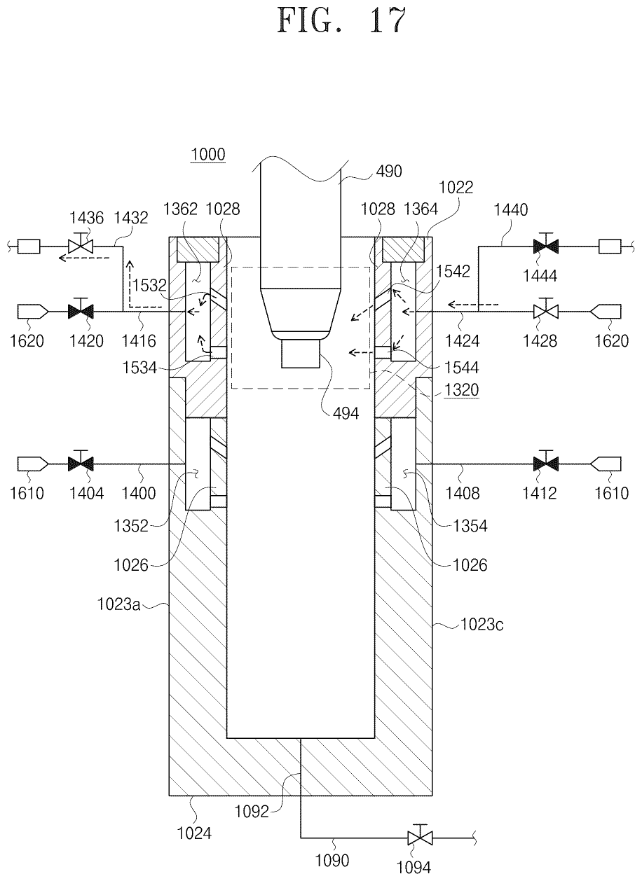

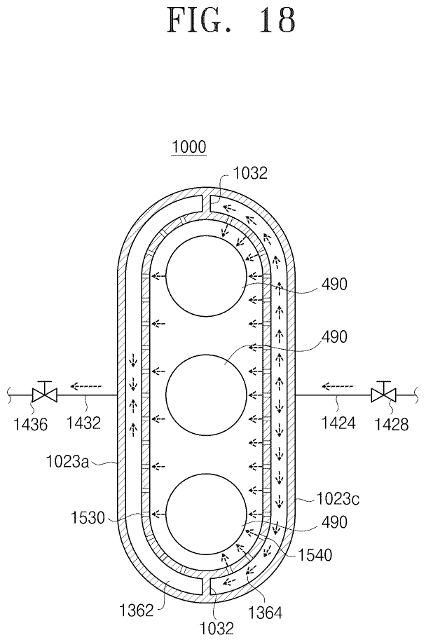

FIG. 8 is a flowchart schematically illustrating a substrate processing method according to an exemplary embodiment of the present invention. FIG. 9 is a cross-sectional view schematically illustrating a position of the nozzle in a cleaning space movement operation of FIG. 8. FIGS. 10 and 11 are a cross-sectional view and a plan view schematically illustrating a flow of a cleaning liquid in a first cleaning operation of FIG. 8, respectively. FIGS. 12 and 13 are a cross-sectional view and a plan view schematically illustrating a flow of a cleaning liquid in a second cleaning operation of FIG. 8, respectively. FIG. 14 is a cross-sectional view schematically illustrating a position of a nozzle in a drying space movement operation of FIG. 8. FIGS. 15 and 16 are a cross-sectional view and a plan view schematically illustrating the flow of gas in a first drying operation of FIG. 8. FIGS. 17 and 18 are a cross-sectional view and a plan view schematically illustrating the flow of gas in a second drying operation of FIG. 8.

In FIGS. 9 to 18, a solid line arrow indicates a flow path of the cleaning liquid, and a dotted arrow indicates a flow path of the gas. In addition, in FIGS. 9 to 18, a valve with a filled inside represents a closed state, and a valve with an empty inside represents an open state.

The substrate processing method includes a substrate processing operation S10 and a nozzle treating operation S20. The substrate processing operation S10 is an operation of liquid-treating the substrate W by supplying the treatment liquid onto the substrate W from the nozzle 490 located at a treatment position. The nozzle treating operation S20 is an operation of cleaning and drying the nozzle 490 by discharging a cleaning liquid and gas toward the nozzle 490 inside the standby port 1000 after the nozzle 490 moves to the inner space 1200 of the standby port 1000 after the substrate processing operation S10.

Referring to FIG. 8, the nozzle treating operation S20 includes a cleaning space movement operation S100, a nozzle cleaning operation S200, a drying space movement operation S300, and a nozzle drying operation S400.

The cleaning space movement operation S100, the nozzle cleaning operation S200, the drying space movement operation S300, and the nozzle drying operation S400 are sequentially performed. The nozzle cleaning operation S200 includes a first cleaning operation S210 and a second cleaning operation S220. The nozzle drying operation S400 includes a first drying operation S410 and a second drying operation S420.

In the cleaning space movement operation S100, as illustrated in FIG. 9, the nozzles 490 are simultaneously inserted into the cleaning space 1310 which may be cleaned by the cleaning liquid as a lower region of the inner space 1200. In the cleaning space movement operation S100, the nozzle tip 494 is located in the cleaning space 1310.s

Next, the nozzle cleaning operation S200 is performed. In the nozzle cleaning operation S200, the first cleaning operation S210 and the second cleaning operation S220 are alternately and repeatedly performed.

In the first cleaning operation S210, as illustrated in FIG. 10, the first liquid valve 1404 is opened and the second liquid valve 1412 is closed. Accordingly, the cleaning liquid is supplied to the cleaning space 1310 only through the first liquid space 1352 between the first liquid space 1352 and the second liquid space 1354.

When the first liquid valve 1404 is opened and the second liquid valve 1412 is closed, the cleaning liquid is supplied to the first liquid space 1352. Referring to FIGS. 10 and 11, a predetermined amount of the cleaning liquid is not directly injected from the first liquid space 1352 to the cleaning space 1310, but is spread along the first liquid space 1352. The cleaning liquid does not flow into the second liquid space 1354 by the first partition wall 1030. The cleaning liquid spreading inside the first liquid space 1352 is injected into the cleaning space 1310 through the first liquid discharge port 1500 of the first inner wall 1026. The cleaning liquid injected through the discharge port 1502 forming the first group among the first liquid discharge ports 1500 is injected toward the nozzle tip 494 in a direction parallel to the direction of the obliquely provided first liquid discharge port 1502. The cleaning liquid injected through the discharge port 1504 forming the second group among the first liquid discharge ports 1500 is injected toward the nozzle tip 494 in the horizontal direction.

Thereafter, the second drying operation S220 is performed. In the second cleaning operation S220, the first liquid valve 1404 is closed and the second liquid valve 1412 is opened as illustrated in FIG. 12. Accordingly, the cleaning liquid is supplied to the cleaning space 1310 only through the second liquid space 1354 between the first liquid space 1352 and the second liquid space 1354.

Referring to FIGS. 12 and 13, a certain amount of cleaning liquid is not directly injected from the second liquid space 1354 into the cleaning space 1310, but is spread along the second liquid space 1354. The cleaning liquid does not flow into the first liquid space 1352 by the first partition wall 1030. The cleaning liquid spreading into the second liquid space 1354 is injected into the cleaning space 1310 through the second liquid discharge port 1510 of the first inner wall 1026. The cleaning liquid injected through the discharge port 1512 forming the first group among the second liquid discharge ports 1510 is injected toward the nozzle tip 494 in a direction parallel to the direction of the obliquely provided second liquid discharge port 1512. The cleaning liquid injected through the discharge port 1514 forming the second group among the second liquid discharge ports 1510 is injected toward the nozzle tip 494 in the horizontal direction. The cleaning liquid injected into the cleaning space 1310 is discharged through the liquid discharge port 1092 formed in the lower surface 1024 of the outer wall 1022.

By alternately performing the first cleaning operation S210 and the second cleaning operation S220, it is possible to prevent a large amount of cleaning liquid from being scattered due to collisions between cleaning liquids compared to when the cleaning liquids are simultaneously discharged in the directions facing each other.

In addition, since the first liquid discharge port 1502 belonging to the first group and the second liquid discharge port 1512 belonging to the first group are formed to be inclined downward, the amount of cleaning liquid scattered is reduced compared to the case where they are formed in the horizontal direction. As a result, it is possible to prevent contamination of the liquid treating chamber 400 by splashing the cleaning liquid to the outside of the standby port 1000.

When the nozzle cleaning operation S200 is completed, the drying space movement operation S300 is performed.

In the drying space movement operation S300, the nozzles 490 vertically move to the drying space 1320 as illustrated in FIG. 14. In the drying space movement operation S300, the nozzle tip 494 is located in the drying space 1320.

Next, a nozzle drying operation S400 is performed. In the nozzle drying operation S400, the first drying operation S410 and the second drying operation S420 are alternately and repeatedly performed.

In the first drying operation S410, the first gas valve 1420 and the second exhaust valve 1444 are opened and the second gas valve 1428 and the first exhaust valve 1436 are closed as illustrated in FIG. 15. Accordingly, the gas is supplied to the drying space 1320 only through the first gas space 1362 between the first gas space 1362 and the second gas space 1364. The gas that has dried the nozzle 490 in the drying space 1320 is exhausted through the second gas space 1364.

When the first gas valve 1420 is opened and the second gas valve 1428 is closed, gas is supplied to the first gas space 1362. Referring to FIGS. 15 and 16, a certain amount of gas is not directly injected from the first gas space 1362 into the drying space 1320, but is spread along the first gas space 1362. The gas does not flow into the second gas space 1364 by the second partition wall 1032. The gas that has spread inside the first gas space 1362 is injected into the drying space 1320 through the first gas discharge port 1530 of the second inner wall 1028. The gas injected through the discharge port 1532 forming the first group among the first gas discharge ports 1530 is injected toward the nozzle tip 494 in a direction parallel to the direction of the obliquely provided first gas discharge port 1532. The gas injected through the discharge port 1534 forming the second group among the first gas discharge ports 1530 is injected toward the nozzle tip 494 in the horizontal direction.

Thereafter, the second drying operation S420 is performed. In the second drying operation S420, as illustrated in FIG. 17, the first gas valve 1420 and the second exhaust valve 1444 are closed, and the second gas valve 1428 and the first exhaust valve 1436 are opened. Accordingly, gas is supplied to the drying space 1320 only through the second gas space 1364 among the first gas space 1362 and the second gas space 1364.

Referring to FIGS. 17 and 18, the gas spreads along the second gas space 1364, and then is injected into the drying space 1320 through the second gas discharge port 1540 of the second inner wall 1028. A certain amount of the gas is not injected directly from the second gas space 1364 into the drying space 1320, but spreads along the second gas space 1364. The gas does not flow into the first gas space 1362 by the second partition 1032. The gas spread inside the second gas space 1364 is injected into the drying space 1320 through the second gas discharge port 1540 of the second inner wall 1028. The gas injected through the discharge port 1532 forming the first group among the second gas discharge ports 1530 is injected toward the nozzle tip 494 in a direction parallel to the direction of the obliquely provided second gas discharge port 1532. The gas injected through the discharge port 1534 forming the second group among the second gas discharge ports 1530 is injected toward the nozzle tip 494 in the horizontal direction.

By alternately supplying the gas as described above, it is possible to solve the scattering problem caused by collisions between gas that occur when the gas is simultaneously supplied.

Since the space in which the gas is supplied and the space in which the gas is exhausted face each other in the first drying operation S410 and the second drying operation S420, the gas may be smoothly exhausted to the outside, and thus the gas is not scattered to the outside.

In addition, since the gas is not supplied from opposite sides at the same time in the nozzle drying operation S400, scattering of the cleaning liquid due to collisions between gas can be prevented and the smooth flow of gas may be facilitated.

In addition, since the first gas discharge ports 1532 belonging to the first group and the second gas discharge ports 1542 belonging to the first group are formed to be inclined downward, the amount of residual cleaning liquid scattered is reduced compared to the case where all the discharge ports are provided in the horizontal direction. As a result, it is possible to prevent contamination of the liquid treating chamber 400 by splashing the cleaning liquid to the outside of the standby port 1000.

Hereinafter, various modified examples of the substrate processing apparatus and the substrate processing method according to the present invention will be described.

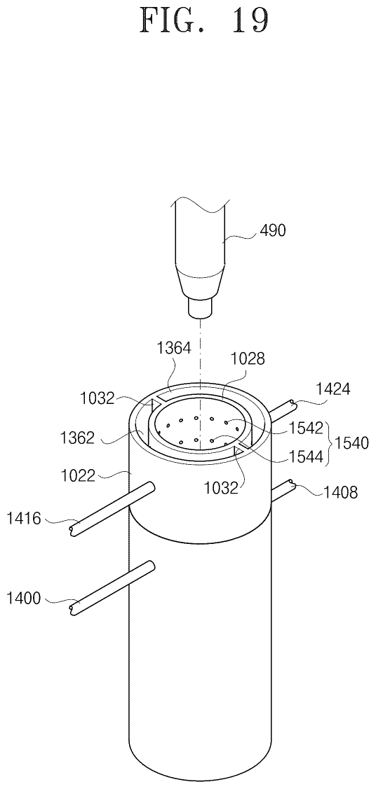

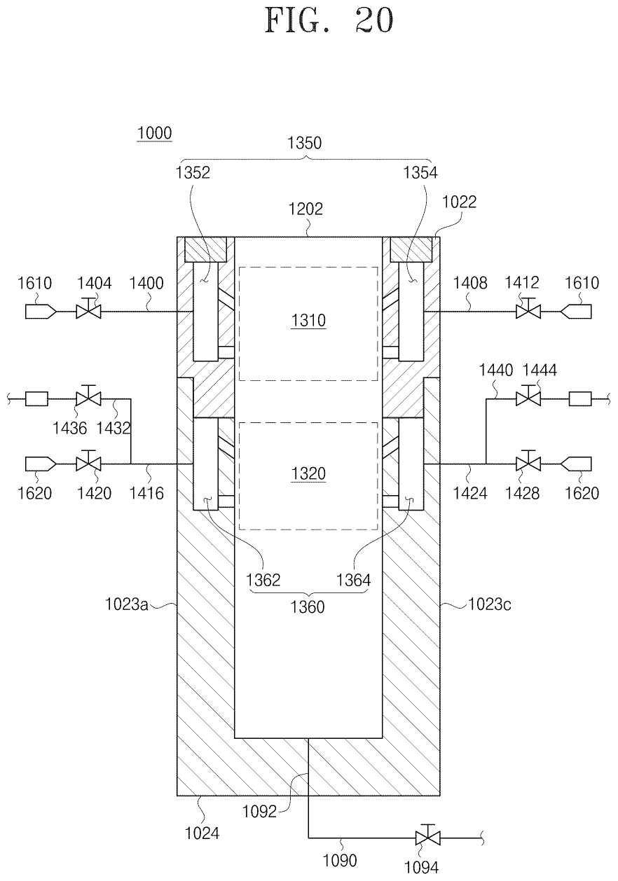

In the above exemplary embodiment, the present invention has been described based on the case where the plurality of nozzles 490 is inserted into the standby port 1000. However, the present invention is not limited thereto. For example, there may be a standby port 1000 in which only one nozzle 490 is inserted into the standby port 1000 to be cleaned and dried, as illustrated in FIG. 19.

In the above exemplary embodiment, the present invention has been described based on the case where the cleaning space 1310 is formed at a lower position than the drying space 1320. Unlike this, however, as illustrated in FIG. 20, the cleaning space 1310 may be formed at a higher position than the drying space 1320. In this case, the nozzle 490 is cleaned in the cleaning space 1310 and then dried in the drying space 1320.

In the above-described exemplary embodiment, the present invention has been described based on the case where in the first inner wall 1026 and the second inner wall 1028, the first liquid discharge port 1502 belonging to the first group, the second liquid discharge port 1512 belonging to the first group, the first gas discharge port 1532 belonging to the first group, and the second gas discharge port 1542 belonging to the first group are formed to be inclined downward toward the cleaning space 1310 or the drying space 1320. However, the present invention is not limited thereto. The first liquid discharge port 1502 belonging to the first group, the second liquid discharge port 1512 belonging to the first group, the first gas discharge port 1532 belonging to the first group, and the second gas discharge port 1542 belonging to the second group may all be formed to discharge the liquid or gas in the horizontal direction.

In the above exemplary embodiment, the first liquid discharge ports 1500, the second liquid discharge ports 1510, the first gas discharge ports 1500, and the second gas discharge ports 1510 have been described to be provided in two rows. However, the present invention is not limited thereto. Among the first liquid discharge ports 1500, the second liquid discharge ports 1510, the first gas discharge ports 1530, and the second gas discharge ports 1540, the liquid discharge ports 1502 and 1512 belonging to the first group and the gas discharge ports 1532 and 1542 belonging to the first group are not provided, the liquid discharge ports 1504 and 1514 belonging to the second group and the gas discharge ports 1534 and 1544 belonging to the second group may not be provided, or the discharge ports 1500, 1510, 1530, and 1540 may be provided to form a plurality of rows, respectively.

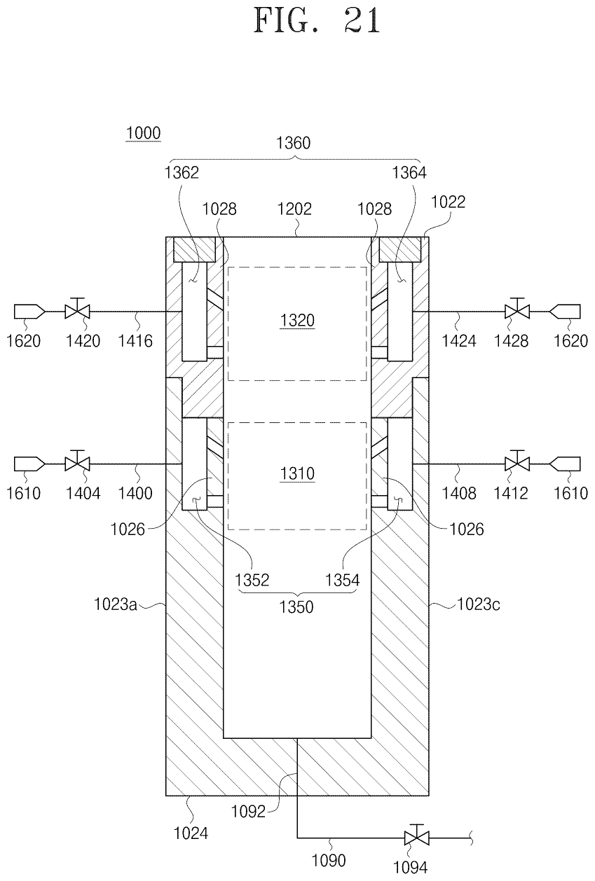

In the above-described exemplary embodiment, the present invention has been described based on the case where the first exhaust pipe 1432 and the second exhaust pipe 1440 are installed to exhaust the atmosphere of the first gas space 1362 and the second gas space 1364. However, the present invention is not limited thereto. Referring to FIG. 21, unlike the above exemplary embodiment, a separate exhaust pipe may not be installed at the standby port 1000.

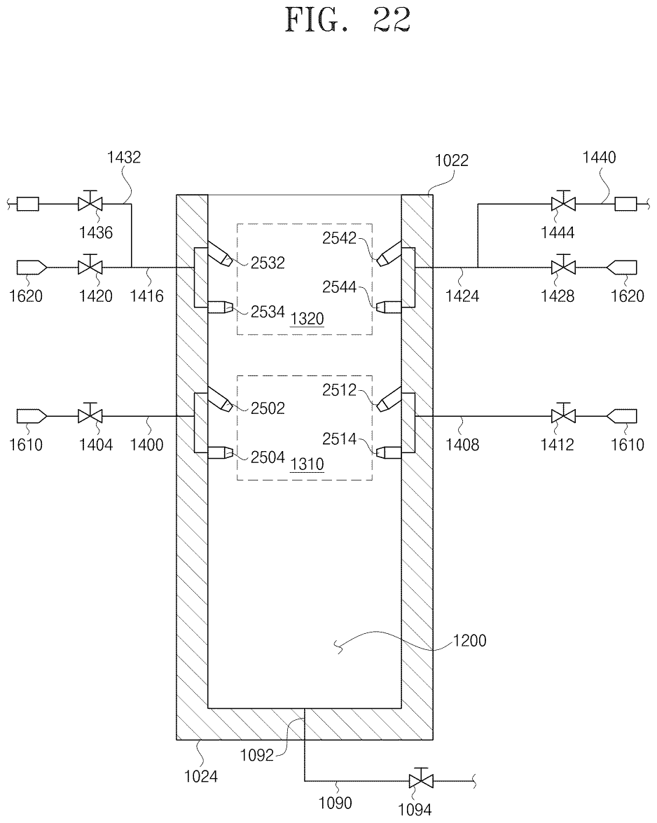

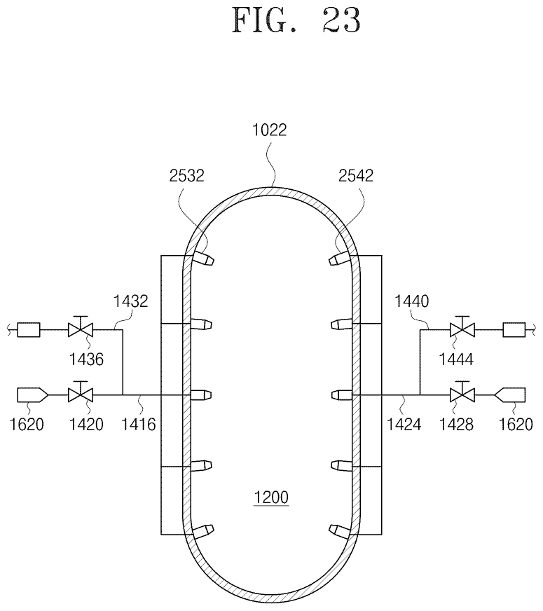

In the above exemplary embodiment, the present invention has been described based on the case where the first inner wall 1026 and the second inner wall 1028 are provided in the inner space 1200. However, this is exemplary, and the first inner wall 1026 and the second inner wall 1028 may not be provided at the standby port according to the present invention. In this case, the discharge ports are provided at the inner wall 1022. Referring to FIGS. 22 and 23, the first liquid discharge port 2502 belonging to the first group and the second liquid discharge port 2512 belonging to the first group are installed to face each other on one side and the other side of the outer wall 1022, respectively, and are provided to discharge the cleaning liquid to be inclined downward toward the inner space 1200 toward one side and the other side of the nozzle 490. The first liquid discharge port 2504 belonging to the second group and the second liquid discharge port 2514 belonging to the second group are installed to face each other at a lower height than the discharge ports 2502 and 2512 belonging to the first group and are provided to discharge the cleaning liquid in the horizontal direction toward the inner space 1200 toward one side and the other side of the nozzle 490, respectively. Similarly, the first gas discharge port 2532 belonging to the first group and the second gas discharge port 2542 belonging to the first group are installed to face each other on one side and the other side of the outer wall 1022, respectively, and provided to discharge the cleaning liquid downwardly inclined toward the inner space 1200, respectively, toward one side and the other side of the nozzle 490. The first gas discharge port 2534 belonging to the second group and the second gas discharge port 2544 belonging to the second group are installed to face each other at a lower height than the discharge ports 2532 and 2542 belonging to the first group and are provided to discharge the cleaning liquid in the horizontal direction toward the inner space 1200 toward one side and the other side of the nozzle 490, respectively.

In the above exemplary embodiment, the present invention has been described based on the case where the first partition wall 1030 for separating the liquid buffer space 1350 into the first liquid space 1352 and the second liquid space 1354 is provided. However, the present invention is not limited thereto. The first partition wall 1030 may not be provided in the liquid buffer space 1350. In this case, the cleaning liquid may be simultaneously supplied to the entire region of the nozzle 490.

In the above exemplary embodiment, the present invention has been described based on the case where the second partition wall 1032 separating the gas buffer space 1360 into the second gas space 1364 and the second gas space 1364 is provided. However, the present invention is not limited thereto. Unlike the above exemplary embodiment, the second partition wall 1032 may not be provided in the gas buffer space 1360. In this case, the gas may be simultaneously supplied to the entire region of the nozzle 490.

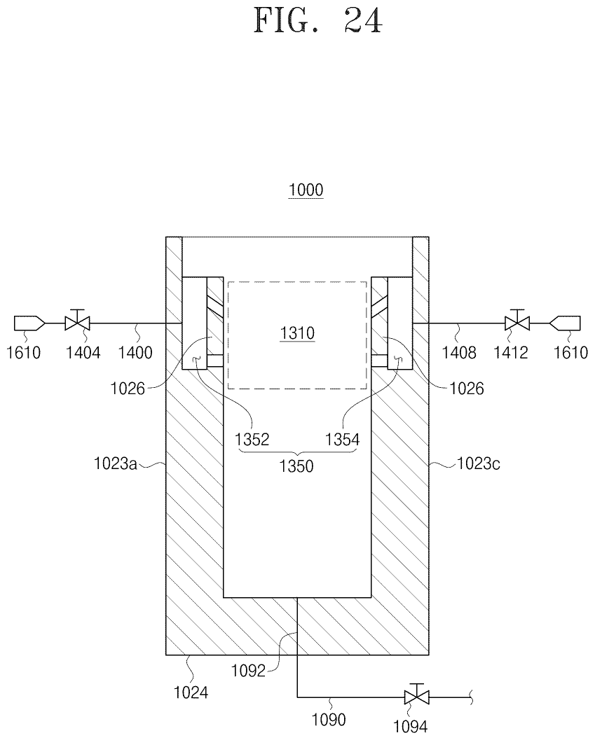

In the above exemplary embodiment, the present invention has been described based on the case where the first inner wall 1026 that divides the lower region of the inner space 1200 into the cleaning space 1310 and the liquid buffer space 1350 and the second inner wall 1028 that divides the upper region of the inner space 1200 into the drying space 1320 and the gas buffer space 1360 are all provided within the outer wall 1022. However, unlike this, as illustrated in FIG. 24, only the first inner wall 1026 that divides the inner space 200 into the cleaning space 1310 and the liquid buffer space 1350 is provided inside the outer wall 1022, and the nozzle 490 may be cleaned only by the cleaning liquid.

In the above-described exemplary embodiment, the present invention has been described based on the case where the first gas discharge port 1530 and the second gas discharge port 1540 are provided to face each other, and the first exhaust port and the second exhaust port are also provided to face each other. However, this is illustrative and the present invention is not limited thereto. A separate first exhaust port and a separate second exhaust port may be installed so that the virtual straight line connecting the first exhaust port and the second exhaust port 1530 is obliquely positioned with respect to the virtual straight line connecting the first gas discharge port 1530 and the second gas discharge port 1540.

In the above-described exemplary embodiment, the present invention has been described based on the case where in the nozzle cleaning method, the plurality of nozzles 490 is simultaneously inserted into the standby port 1000 to be cleaned. However, the number of nozzles 490 inserted into the standby port 1000 is not limited thereto, and only one nozzle 490 may be inserted to be cleaned and dried.

In the above-described exemplary embodiment, the present invention has been described based on the case where in the substrate processing method, the cleaning space movement operation S100, the nozzle cleaning operation S200, the drying space movement operation S300, and the nozzle drying operation S400 are sequentially performed. However, the present invention is not limited thereto, and a secondary drying space movement operation S500 and a secondary drying operation S600, which are performed after the nozzle drying operation S400, may be further included.

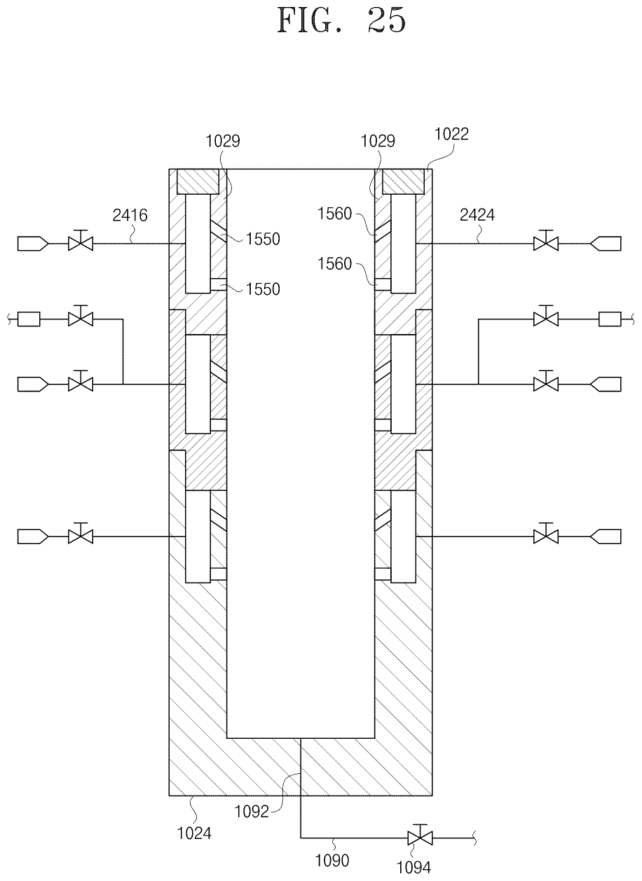

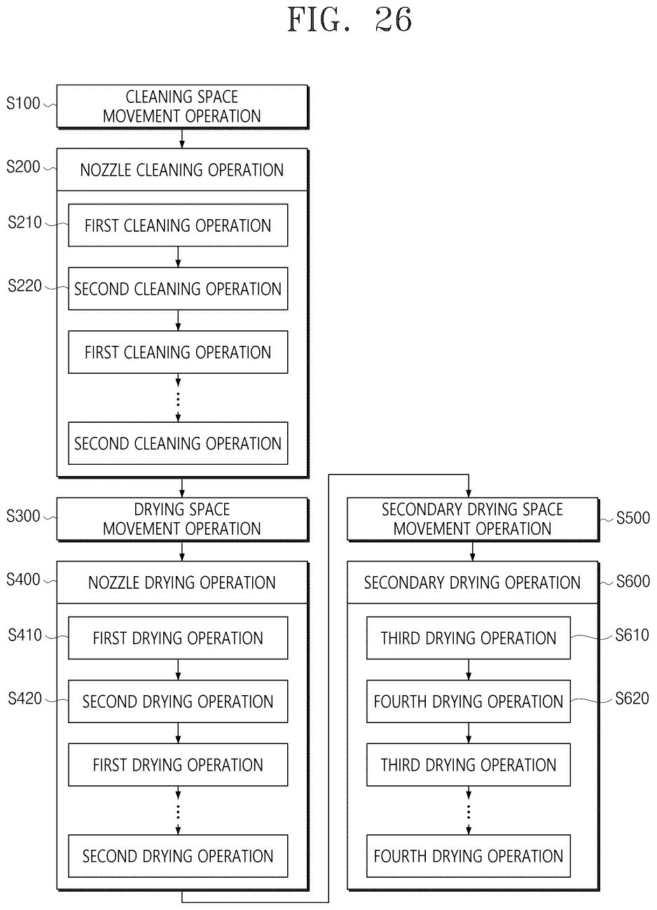

FIG. 25 is a cross-sectional view schematically illustrating another exemplary embodiment of the standby port according to the exemplary embodiment of the present invention, and FIG. 26 is a flowchart schematically illustrating an exemplary embodiment of a substrate processing method according to the standby port of FIG. 25.

Referring to FIG. 25, the standby port 1000 further includes a third gas discharge port 1550 provided at a higher position than the first gas supply pipe 1416 and a fourth gas discharge port 1560 provided at a higher position than the second gas supply pipe 1424. According to the exemplary embodiment, the third gas discharge port 1550 and the fourth gas discharge port 1560 may be provided at opposite positions. According to the exemplary embodiment, the standby port 1000 may have a third inner wall 1029 provided at an upper portion of the second inner wall 1028.

Referring to FIG. 26, after the nozzle drying operation S400 is completed, a secondary drying space movement operation S500 and a secondary drying operation S600 are sequentially performed. In the secondary drying space movement operation S500, the nozzle 490 moves upward in the inner space 1200. The secondary drying operation S600 includes a third drying operation S610 and a fourth drying operation S620. The third drying operation S610 is an operation of drying the nozzle 490 by supplying gas from one side of the outer wall 1022 through the third gas discharge port 1550. The fourth drying operation S620 is an operation of drying the nozzle 490 by supplying gas from the other side of the outer wall 1022 through the fourth gas discharge port 1560. According to the exemplary embodiment, the third drying operation S610 and the fourth drying operation S620 may be alternately and repeatedly performed. According to the exemplary embodiment, the pressure of the gas supplied in the secondary drying operation S600 performed by the third gas supply pipe 2416 and the fourth gas supply pipe 2424 may be lower than the pressure of the gas supplied in the nozzle drying operation S400.

In addition, in the above-described exemplary embodiment, the present invention has been described based on the apparatus for performing the cleaning process of removing foreign substances on the substrate W or removing the thin film on the substrate W by supplying a treatment liquid as an example. However, the technical idea of the present invention is not limited thereto. The standby port according to the present invention may be applied to an apparatus for forming a film, such as a resist film, on the substrate W.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a cup unit having a treatment space for liquid-treating a substrate with a treatment liquid;
a support unit for supporting the substrate within the treatment space;
a nozzle unit including a nozzle that supplies a treatment liquid to the substrate supported by the support unit; and
a standby port which is positioned on one side of the cup unit and in which the nozzle is located after supplying the treatment liquid,
wherein the standby port includes:
an outer wall with an inner space;
a first gas discharge port provided to supply gas toward one side of the nozzle accommodated in the standby port; and
a second gas discharge port provided to supply gas independently of the first gas discharge port toward the other side of the nozzle accommodated in the standby port, and
the first gas discharge port and the second gas discharge port are provided at mutually opposite positions.

2. The apparatus of claim 1, wherein the standby port includes:
a first exhaust port that is arranged opposite a region where the second gas discharge port is provided to exhaust an atmosphere from the inner space to the outside; and
a second exhaust port that is arranged opposite a region where the first gas discharge port is provided to exhaust an atmosphere from the inner space to the outside.

3. The apparatus of claim 2, wherein the first exhaust pipe connected to the first exhaust port is connected to the first gas supply pipe, which is connected to the first gas discharge port to supply gas,
the second exhaust pipe connected to the second exhaust port is connected to the second gas supply pipe, which is connected to the second gas discharge port to supply gas,
the first gas discharge port is configured to function as the first exhaust port, and
the second gas discharge port is configured to function as the second exhaust port.

4. The apparatus of claim 1, wherein a part of the first gas discharge ports is provided to be inclined downward toward the inner space, and
a part of the second gas discharge ports is provided to be inclined downward toward the inner space.

5. The apparatus of claim 4, wherein another part of the first gas discharge ports is provided to discharge gas in a horizontal direction toward the inner space,
among the first gas discharge ports, a first gas discharge port for discharging gas in a downwardly inclined direction is disposed above the first gas discharge ports that discharge gas in a horizontal direction, and
another part of the second gas discharge ports is provided to discharge gas in a horizontal direction toward the inner space, and
among the second gas discharge ports, a second gas discharge port for discharging gas in a downwardly inclined direction is disposed above the second gas discharge ports that discharge gas in a horizontal direction.

6. The apparatus of claim 1, wherein the standby port includes:
a first liquid discharge port that supplies a cleaning liquid toward one side of the nozzle accommodated in the standby port; and
a second liquid discharge port that supplies a cleaning liquid toward the other side of the nozzle accommodated in the standby port, and
the first liquid discharge port and the second liquid discharge port are provided at opposite positions.

7. The apparatus of claim 6, wherein the first liquid discharge port and the second liquid discharge port are provided at lower positions than the first gas discharge port and the second gas discharge port.

8. The apparatus of claim 6, wherein a part of the first liquid discharge ports is provided to be inclined downward toward the inner space,
a part of the second liquid discharge ports is provided to be inclined downward toward the inner space,
another part of the first liquid discharge ports is provided to discharge a cleaning liquid in a horizontal direction toward the inner space,
another part of the second liquid discharge ports is provided to discharge a cleaning liquid in a horizontal direction toward the inner space,
among the first liquid discharge ports, a first liquid discharge port for discharging a cleaning liquid in a downwardly inclined direction is disposed above the first liquid discharge ports that discharge a cleaning liquid in a horizontal direction, and
among the second liquid discharge ports, a second liquid discharge port for discharging a cleaning liquid in a downwardly inclined direction is disposed above the second liquid discharge ports that discharge a cleaning liquid in a horizontal direction.

9. The apparatus of claim 1, wherein the standby port includes:
a second inner wall, which is provided in the inner space, and divides the inner space into a drying space where the nozzle is positioned and dried, and a gas buffer space formed outside the drying space and provided in a ring shape surrounding the drying space; and
a second partition wall provided in the gas buffer space and separating the gas buffer space into a first gas space and a second gas space, and
the first gas discharge port and the second gas discharge port are formed in the second inner wall.

10. The apparatus of claim 9, wherein the first gas discharge port and the second gas discharge port are formed to form rows in a direction along a circumference of the second inner wall,
a plurality of rows is provided in a vertical direction, and
the first gas discharge port and the second gas discharge port constituting the row disposed at the top of the rows are formed to be inclined downward toward the drying space.

11. The apparatus of claim 9, wherein the standby port includes:
a first inner wall that is provided in the inner space and divides the inner space into a cleaning space where the nozzle is positioned and cleaned, and a liquid buffer space formed outside the cleaning space and provided in a ring shape surrounding the cleaning space;
a first partition wall provided in the liquid buffer space and separating the liquid buffer space into a first liquid space and a second liquid space;
a first liquid discharge port that supplies a cleaning liquid toward one side of the nozzle accommodated in the standby port; and
a second liquid discharge port that supplies a cleaning liquid toward the other side of the nozzle accommodated in the standby port, and
the first liquid discharge port and the second liquid discharge port are formed in the first inner wall to allow the cleaning liquid to flow between the liquid buffer space and the cleaning space.

12-19. (canceled)

20. An apparatus for processing a substrate, the apparatus comprising:
a cup unit having a treatment space for liquid-treating a substrate with a treatment liquid;
a support unit for supporting the substrate within the treatment space;
a nozzle unit including a nozzle that supplies a treatment liquid to the substrate supported by the support unit; and
a standby port which is located on one side of the cup unit and in which the nozzle is located after supplying the treatment liquid,
the standby port includes:
an outer wall with an inner space;
a first inner wall that is provided in the inner space and divides the inner space into a cleaning space where the nozzle is positioned and cleaned, and a liquid buffer space formed outside the cleaning space and provided in a ring shape surrounding the cleaning space;
a second inner wall that is provided in the inner space, and divides the inner space into a drying space where the nozzle is positioned and is dried at a position higher than the cleaning space, and a gas buffer space formed outside the drying space and provided in a ring shape surrounding the drying space;
a first partition wall provided in the liquid buffer space and separating the liquid buffer space into a first liquid space and a second liquid space;
a second partition wall provided in the gas buffer space and separating the gas buffer space into a first gas space and a second gas space;
a first liquid discharge port that supplies a cleaning liquid toward one side of the nozzle accommodated in the standby port;
a second liquid discharge port that supplies a cleaning liquid toward the other side of the nozzle accommodated in the standby port;
a first gas discharge port that supplies gas toward one side of the nozzle accommodated in the standby port;
a second gas discharge port that supplies gas toward the other side of the nozzle accommodated in the standby port;
a first exhaust port that exhausts an atmosphere from one side of the nozzle accommodated in the standby port to the outside; and
a second exhaust port that exhausts an atmosphere from the other side of the nozzle accommodated in the standby port to the outside,
the first gas discharge port and the second gas discharge port are provided at mutually opposite positions,
the first liquid discharge port and the second liquid discharge port are provided at mutually opposite positions,
the first gas discharge port is configured to function as the first exhaust port, and
the second gas discharge port is configured to function as the second exhaust port.
